(19) United States
(12) Patent Application Publication
(10) Pub. No.: US 2026/0078267 A1
(43) Pub. Date: Mar. 19, 2026

(54) QUANTUM-DOT LIGHT CONVERSION FILM, PREPARATION METHOD AND APPLICATION THEREOF AND ANTI-ULTRAVIOLET BLUE-FREE YELLOW LIGHT FOR CHIP PROCESS

(71) Applicant: Taijia Corporation, Kobe (JP)

(72) Inventor: Tianyi QIU, Kobe (JP)

(73) Assignee: Taijia Corporation, Kobe (JP)

(21) Appl. No.: 19/089,046

(22) Filed: Mar. 25, 2025

(30) Foreign Application Priority Data
Sep. 14, 2024 (CN) 202411295497.4

(51) Int. Cl. C09D 5/22; C09D 7/40; C09D 7/61; C09D 133/08; H01L 25/075; H10H 29/01; H10H 29/851

(52) U.S. Cl. CPC C09D 5/22; C09D 7/61; C09D 7/67; C09D 7/68; C09D 133/08; H10H 29/0361; H10H 29/8512; H10W 90/00

(57) ABSTRACT

A quantum-dot light conversion film, a preparation method and an application thereof and an anti-ultraviolet blue-free yellow light for chip manufacturing are provided. The preparation method includes: (1) mixing a quantum-dot concentrate with an acrylic monomer, then adding high polymer for secondary mixing, to obtain a polymer; (2) after mixing the polymer and nanoparticles, adding additives for dispersion to obtain a light conversion liquid resin; and (3) coating and curing the light conversion liquid resin to obtain a quantum-dot light conversion film. The light conversion film has high light conversion efficiency, adjustable emission peak position and narrow half peak width. Its surface forms a tightly arranged high refractive index microlens structure. When the light reaches the microlens array, as the light output surface is a lens structure and the refractive index is improved, more light is emitted in the positive direction, thereby effectively improving the light output rate.

### CROSS REFERENCE TO THE RELATED APPLICATIONS

This application is based upon and claims priority to Chinese Patent Application No. 202411295497.4, filed on Sep. 14, 2024, the entire contents of which are incorporated herein by reference.

### TECHNICAL FIELD

The present disclosure relates to the technical field of optical materials, and in particular to a quantum-dot light conversion film, a preparation method and an application thereof and an anti-ultraviolet blue-free yellow light for chip process.

### BACKGROUND

In view of the performance of the photoresist in the yellow light process and the yield of the lithography process, considering the visual function of the human eye to light wave, the yellow light chamber of the chip process should be illuminated by a special light. The traditional scheme adopts the scheme of a fluorescent lamp tube and filter, which filters the wavelength below 500 nm. In recent years, the popular light emitting diode (LED) lamp plus filter scheme filters the wavelength of 520 nm or less light. With the updated iteration of the chip, process chips below 5 nm show low power consumption and super computing power. With the updated iteration of the chip, process chips below 5 nm show low power consumption and super computing power. However, the 5 nm process puts forward higher requirements for lighting, the light with a wavelength below 535 nm needs to be completely cut off, and the above traditional fluorescent tubes and LED tubes cannot meet the process below 5 nm.

With the continuous advancement of the chip process, yellow lighting has hardly changed. The traditional white fluorescent lamp is superimposed with a yellow fluorescent coating to obtain light with a cut-off wavelength of more than 500 nm. The efficiency of the LED light-emitting chips is much higher than that of the fluorescent lamp, being widely used in the field of lighting. It uses a high-efficiency blue LED to excite different proportions of phosphors, and then superimposes the filter scheme to obtain light with a cutoff wavelength of more than 520 nm, and has a higher luminous flux and a lower calorific value. Because the conversion efficiency of the phosphor is not high, the spectrum contains a large amount of blue light components, and the light energy will be greatly lost after the filter is filtered. Therefore, providing a light source suitable for the yellow light process has become an urgent problem that needs to be solved.

### SUMMARY

An objective of the present disclosure is to overcome the defects in the prior art and provide a quantum-dot light conversion film, a preparation method and an application thereof and an anti-ultraviolet blue-free yellow light for chip process.

In order to achieve the above effects, the present disclosure adopts the following technical solutions.

The present disclosure provides a preparation method of a quantum-dot light conversion film, including the following steps:
(1) mixing a quantum-dot concentrate with an acrylic monomer, then adding high polymer for secondary mixing, to obtain a polymer;
(2) after mixing the polymer and nanoparticles, adding additives for dispersion to obtain a light conversion liquid resin; and
(3) coating and curing the light conversion liquid resin to obtain a quantum-dot light conversion film.

As a preferred option, in step (1), a wavelength of the quantum-dot concentrate is 580-600 nm;
a mass ratio of the quantum-dot concentrate to the acrylic monomer is (1-20):(5-50);
in step (1), the polymer is acrylic and/or thiol; and
in step (1), a mass ratio of the quantum-dot concentrate to the high polymer is (1-20):(5-50).

As a preferred option, in step (2), the nanoparticles are TiO₂ or ZrO₂; and a particle size of the nanoparticles is 50-500 nm;
in step (1), a mass ratio of the quantum-dot concentrate to the nanoparticles described in step (2) is (1-20):(0.5-5);
in step (2), additives include polymerization inhibitors and photoinitiators;
a mass of the polymerization inhibitors is 0.01-0.2% of a mass of the light conversion liquid resin in step (2); and
a mass of the photoinitiators is 0.5-2% of a mass of the light conversion liquid resin in step (2).

As a preferred option, in step (3), a substrate for coating is alumina or silicon; and a thickness of the substrate is 12-120 μm;
in step (3), a thickness of the glue for coating is 50-200 μm; and
in step (3), an irradiation energy for curing is 500-3000 mJ/cm².

The present disclosure further provides a quantum-dot light conversion film prepared by the preparation method.

The present disclosure further provides an application of the quantum-dot light conversion film in the anti-ultraviolet blue-free yellow light for chip process.

The present disclosure further provides an anti-ultraviolet blue-free yellow light for chip process, a structure of the anti-ultraviolet blue-free yellow light for chip process is from top to bottom: a quantum-dot light conversion film, a thermal insulation film, an optically clear adhesive (OCA) glue layer, a transparent silica gel layer, and a mini-LED blue chip light source are described.

As a preferred option, the transparent silica gel layer contains nanoparticles; and the nanoparticles are TiO₂ or ZrO₂; and
a mass of the nanoparticles is 0.5-5% of a mass of the transparent silica gel layer.

As a preferred option, the OCA glue layer contains nanoparticles; and the nanoparticles are TiO₂ or ZrO₂; and
a mass of the nanoparticles is 1-40% of a mass of the OCA glue layer.

The present disclosure provides a preparation method of a quantum-dot light conversion film, including the following steps: (1) mixing a quantum-dot concentrate with an acrylic monomer, then adding high polymer for secondary mixing, to obtain a polymer; (2) after mixing the polymer and nanoparticles, adding additives for dispersion to obtain a light conversion liquid resin; and (3) coating and curing the light conversion liquid resin to obtain a quantum-dot light conversion film. In the present disclosure, the light conversion liquid resin is coated on a water-blocking and oxygen-blocking film, after covering a layer of water and oxygen barrier film, the light conversion film of sandwich structure is formed by UV curing. The light conversion film not only has the characteristics of high light conversion efficiency, adjustable emission peak position, narrow half peak width and so on, the surface of the film can also be printed with various inks, the special optical structure is designed on the surface of the film to meet the requirements of light scattering, and it has excellent heat resistance and weather resistance. The surface of the light conversion film in the present disclosure forms a tightly arranged high refractive index microlens structure. When the light reaches the microlens array, as the light output surface is a lens structure and the refractive index is improved, as much light as possible is emitted in the positive direction, thereby effectively improving the light output rate.

The present disclosure provides an anti-ultraviolet blue-free yellow light for the chip process, a structure of the the anti-ultraviolet blue-free yellow light for the chip process is from top to bottom: a quantum-dot light conversion film, a thermal insulation film, an OCA glue layer, a transparent silica gel layer, and a mini-LED blue chip light source are described. In the present disclosure, the yellow light uses the mini-LED blue chip to excite the quantum dot material, and converts blue light into yellow light of a specific wavelength, which has the characteristics of high luminous efficiency, no blue-green light below 535 nm, and no crystallization and curing of photosensitive materials such as photoresist. The luminous efficiency and uniformity of mini-LED chips are much higher than those of ordinary LED chips. And because the mini-LED drive current is small, and has less calorific value, long life and other characteristics, and luminaires prepared by quantum dot films with specific wavelengths stimulated by the mini-LED.

### BRIEF DESCRIPTION OF THE DRAWINGS

FIG. 1 is a top view sketch of a base structure in Embodiment 1;

FIG. 2 is a structure diagram of an application thereof and an anti-ultraviolet blue-free yellow light for chip process in Embodiment 1;

FIG. 3 is a spectrum of an anti-ultraviolet blue-free yellow light for chip process in Embodiment 1; and

FIG. 4 shows a chromaticity diagram of an anti-ultraviolet blue-free yellow light for chip process in Embodiment 1.

### DETAILED DESCRIPTION OF THE EMBODIMENTS

The present disclosure provides a preparation method of a quantum-dot light conversion film, including the following steps:
(1) mixing a quantum-dot concentrate with an acrylic monomer, then adding high polymer for secondary mixing, to obtain a polymer;
(2) after mixing the polymer and nanoparticles, adding additives for dispersion to obtain a light conversion liquid resin; and
(3) coating and curing the light conversion liquid resin to obtain a quantum-dot light conversion film.

In the present disclosure, in step (1), a wavelength of the quantum-dot concentrate is preferably 580-600 nm, further preferably 585-595 nm, and more preferably 588-590 nm.

In the present disclosure, the quantum-dot concentrate may be obtained by commercially available.

In the present disclosure, a mass ratio of the quantum-dot concentrate and the acrylic monomer is preferably (1-20):(5-50), further preferably (5-1):(1-40), and more preferably (8-12):(20-30).

In the present disclosure, in step (1), the polymer is acrylic and/or thiol.

In the present disclosure, in step (1), a mass ratio of the quantum-dot concentrate and the polymer is preferably (1-20):(5-50), further preferably (5-15):(10-40), and more preferably (8-12):(20-30).

In the present disclosure, in step (1), a rotational speed for mixing is preferably 200-1000 rpm, further preferably 300-800 rpm, and more preferably 400-600 rpm; a mixing time is preferably 20-60 min, further preferably 30-50 min, and more preferably 35-45 min.

In the present disclosure, in step (1), a rotational speed for the secondary mixing is preferably 200-1000 rpm, further preferably 300-800 rpm, and more preferably 400-600 rpm; a time of the secondary mixing is preferably 20-60 min, further preferably 30-50 min, and more preferably 35-45 min.

In the present disclosure, in step (2), the nanoparticles are TiO₂ or ZrO₂; a particle size of nanoparticles is preferably 50-500 nm, further preferably 100-400 nm, and more preferably 200-300 nm.

In the present disclosure, in step (1), a mass ratio of the quantum-dot concentrate to the nanoparticles described in step (2) is preferably (1-20):(0.5-5), and preferably (5-15):(1-4) and (8-12):(2-3).

In the present disclosure, in step (2), a mixing speed is preferably 200-1000 rpm, further preferably 300-800 rpm, and more preferably 400-600 rpm; a mixing time is preferably 20-60 min, further preferably 30-50 min, and more preferably 35-45 min.

In the present disclosure, in step (2), the additives include polymerization inhibitors and photoinitiators.

In the present disclosure, polymerization inhibitors and photoinitiators are commercially available products.

In the present disclosure, a mass of the inhibitors is 0.01-0.2% of a mass of the liquid glue in step (2).

In the present disclosure, a mass of photoinitiators is 0.5-2% of a mass of photoconversion liquid glue in step (2).

In the present disclosure, in step (2), a dispersed speed is preferably 200-1000 rpm, further preferably 300-800 rpm, and more preferably 400-600 rpm; a dispersion time is preferably 20-60 min, further preferably 30-50 min, and more preferably 35-45 min.

In the present disclosure, in step (3), a substrate for coating is alumina or silicon; a thickness of the substrate is preferably 12-120 μm, further preferably 20-100 μm, and more preferably 40-60 μm.

In the present disclosure, the substrate has the function of water and oxygen resistance, and the substrate is alumina or silicon deposited by PECVD or magnetron sputtering.

In the present disclosure, in step (3), a glue thickness for the coating is preferably 50-200 μm, further preferably 80-150 μm, and more preferably 100-120 μm.

In the present disclosure, the light-converted liquid glue is coated on the surface of the substrate by multi-roll coating, slit coating, and drop coating, then a layer of substrate is covered on the surface of the glue to form a sandwich structure.

In the present disclosure, in step (3), an irradiation energy for curing is 500-3000 mJ/cm², further preferably 1000-2000 mJ/cm², and more preferably 1500-1800 mJ/cm²; and using ultraviolet irradiation.

The present disclosure also provides a quantum-dot light conversion film prepared by the preparation method of the quantum-dot light conversion film.

The present disclosure also provides an application of the quantum-dot light conversion film in the anti-ultraviolet blue-free yellow light for chip process.

The present disclosure further provides an anti-ultraviolet blue-free yellow light for chip process, a structure of the anti-ultraviolet blue-free yellow light for chip process is from top to bottom: the quantum-dot light conversion film, a thermal insulation film, an OCA adhesive layer, a transparent silica gel layer, a mini-LED blue chip light source.

In the present disclosure, a material of the thermal insulation film is acrylic or PC.

In the present disclosure, the light source of the mini-LED blue chip is implanted into the substrate, and a milky white shading ink layer is arranged vertically upward around the light-emitting area of the chip, then silica gel is injected into it to form a silica gel layer.

In the present disclosure, the transparent silica gel layer contains nanoparticles; and the nanoparticles are TiO₂ or ZrO₂.

In the present disclosure, a mass of nanoparticles is preferably 0.5-5% of a mass of transparent silica gel layer, further preferably 1-4%, and more preferably 2-3%.

In the present disclosure, the silica gel layer doped with nanoparticles has excellent stability and heat resistance.

In the present disclosure, the OCA adhesive layer contains nanoparticles; and the nanoparticles are TiO₂ or ZrO₂.

In the present disclosure, a mass of the nanoparticles is preferably 1-40% of the mass of the OCA adhesive layer, further preferably 5-35%, and more preferably 10-20%.

In the present disclosure, the OCA adhesive layer plays a role of adhesion, and has its own temperature resistance, softness and high light transmittance.

In the present disclosure, a quantum-dot light conversion film is attached to the thermal insulation film to obtain yellow light with the main emission peak in the 580-600 nm band, the yellow light is filtered through an external filter to remove the weak blue light that is not converted into yellow light, and a yellow light that does not contain the band below 535 nm is obtained.

In the following, the technical schemes provided by the present disclosure are described in detail in combination with the implementation examples, but they cannot be understood as limiting the scope of protection of the present disclosure.

### Embodiment 1

The quantum-dot concentrate with a wavelength of 590 nm was taken, a mass ratio of quantum dot solution to acrylic monomer was controlled to be 10:30, the two were mixed and stirred at 500 rpm for 40 min, the two were mixed and stirred at 500 rpm for 40 min, then acrylic was added (a mass ratio of concentrated quantum dot solution and acrylic was 10:25), the polymer was obtained by stirring at 500 rpm for 40 min; then TiO₂ (a particle size of 100 nm) was added, a mass ratio of quantum dot solution and nanoparticles was controlled at 10:1, being stirring at 500 rpm for 40 min; then the commercially available inhibitor and photoinitiator were added, and the mass of the inhibitor was 0.1% of the mass of the photoconverted liquid glue, a mass of the photoinitiator is 1% of a mass of the photoconverted liquid glue, and the photoconverted liquid glue was obtained by stirring at 500 rpm for 40 min; the light-converted liquid glue is coated on the surface of the water-resistant and oxygen-resistant alumina substrate (a thickness of 80 μm) by a slit coating method, a thickness for the coating was 100 μm, and then the same water-resistant and oxygen-resistant alumina substrate was continued to cover the surface of the glue to form a sandwich structure. The quantum-dot light conversion film was obtained by UV irradiation, and the irradiation energy was controlled at 1500 mJ/cm².

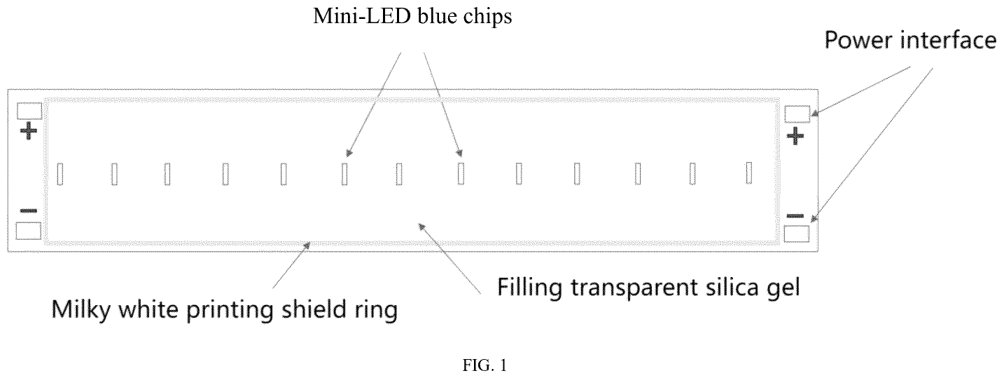

The mini-LED blue light chip was implanted on the surface of the aluminum substrate, and a milky white shading ink layer was set up vertically around the substrate. Silica gel was injected into the enclosure formed by the ink layer to form a silica gel layer. The silica gel layer contains TiO₂, and the mass of TiO₂ was 1% of the mass of the silica gel layer. The substrate, milky white shading ink layer and silica gel layer are the substrate structure. The top view of the substrate structure is shown in FIG. 1.

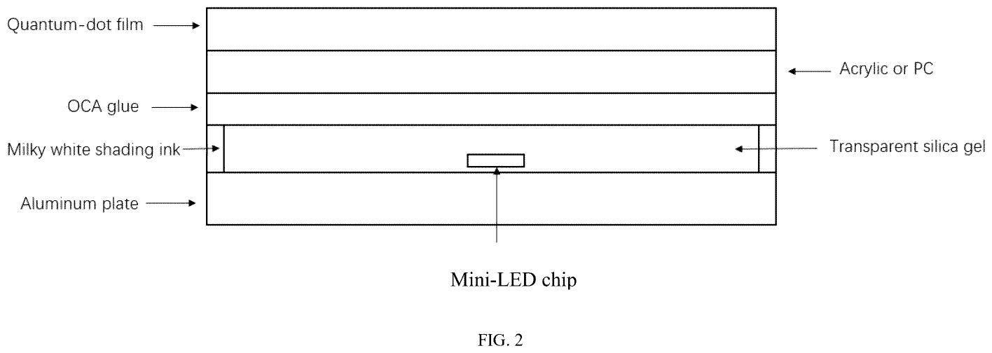

OCA adhesive was coated on the surface of silica gel layer (OCA adhesive layer contains TiO₂, and the mass of TiO₂ was 10 % of the mass of OCA adhesive layer), insulation film was set on the surface of OCA adhesive layer (acrylic or PC was used as insulation film), a quantum-dot light conversion film is coated on the surface of the heat insulation film, i.e. a an anti-ultraviolet blue-free yellow light for chip process was obtained, and the structure diagram was shown in FIG. 2.

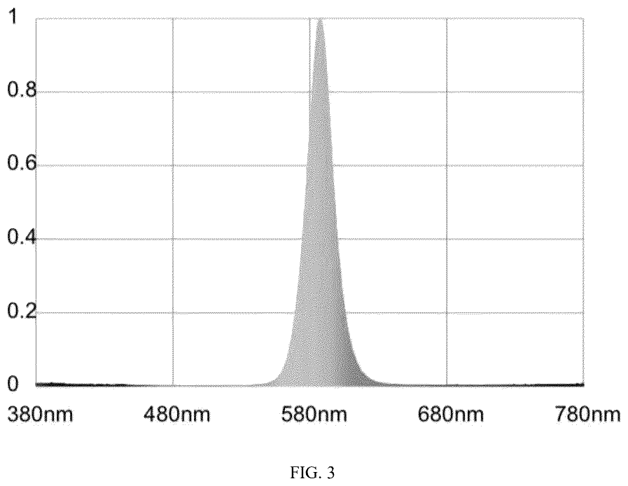

The performance of the yellow light prepared by this example is tested, and the spectrum is shown in FIG. 3. The ordinate was the relative spectral intensity, and the abscissa was the spectral wavelength. It can be seen from FIG. 3 that the cut-off wavelength of the yellow light prepared by Example 1 was greater than or equal to 535 nm.

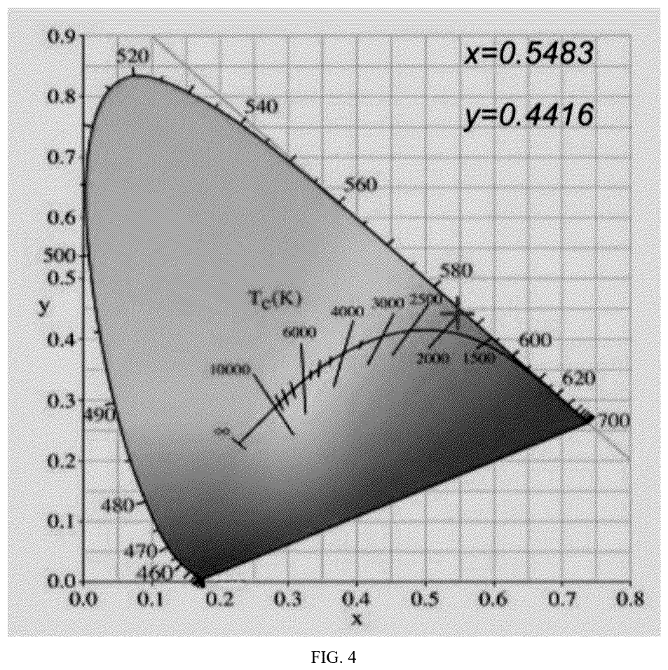

The yellow light prepared by the present embodiment was tested for performance. The chromaticity diagram was shown in FIG. 4. It can be seen from FIG. 4 that the white point coordinates of the yellow light of Embodiment 1 were x=0.5483, y=0.4416.

The above is only the preferred implementation method of the invention. It should be pointed out that for ordinary technicians in the technical field, some improvements and embellishments can be made without breaking away from the principle of the invention. These improvements and embellishments should also be regarded as the scope of protection of the present disclosure.

What is claimed is:

1. A preparation method of a quantum-dot light conversion film, comprising the following steps:
(1) mixing a quantum-dot concentrate with an acrylic monomer, and then adding a high polymer for a secondary mixing, to obtain a polymer;
(2) after mixing the polymer and nanoparticles, adding additives for a dispersion to obtain a light conversion liquid resin; and
(3) coating and curing the light conversion liquid resin to obtain the quantum-dot light conversion film.

2. The preparation method of the quantum-dot light conversion film according to claim 1, wherein in the step (1), a wavelength of the quantum-dot concentrate is 580-600 nm;
a mass ratio of the quantum-dot concentrate to the acrylic monomer is (1-20):(5-50);
in the step (1), the high polymer is acrylic and/or thiol; and
in the step (1), a mass ratio of the quantum-dot concentrate to the high polymer is (1-20):(5-50).

3. The preparation method of the quantum-dot light conversion film according to claim 1, wherein the nanoparticles are TiO₂ or ZrO₂; and a particle size of the nanoparticles is 50-500 nm;
a mass ratio of the quantum-dot concentrate in the step (1) to the nanoparticles in the step (2) is (1-20):(0.5-5);
in the step (2), the additives comprise polymerization inhibitors and photoinitiators;
a mass of the polymerization inhibitors is 0.01-0.2% of a mass of the light conversion liquid resin in the step (2); and
a mass of the photoinitiators is 0.5-2% of the mass of the light conversion liquid resin in the step (2).

4. The preparation method of the quantum-dot light conversion film according to claim 3, wherein in the step (3), a substrate for coating is alumina or silicon; and a thickness of the substrate is 12-120 μm;
in the step (3), a thickness of the light conversion liquid resin for coating is 50-200 μm; and
in the step (3), an irradiation energy for curing is 500-3000 mJ/cm².

5. A quantum-dot light conversion film prepared by the preparation method according to claim 1.

6. The quantum-dot light conversion film according to claim 5, wherein the quantum-dot light conversion film is used in an anti-ultraviolet blue-free yellow light for a chip process.

7. An anti-ultraviolet blue-free yellow light for a chip process, wherein a structure of the anti-ultraviolet blue-free yellow light for the chip process comprises from top to bottom: the quantum-dot light conversion film according to claim 5, a thermal insulation film, an optically clear adhesive (OCA) glue layer, a transparent silica gel layer, and a mini-light emitting diode (LED) blue chip light source.

8. The anti-ultraviolet blue-free yellow light for the chip process according to claim 7, wherein the transparent silica gel layer comprises nanoparticles; and the nanoparticles in the transparent silica gel layer are TiO₂ or ZrO₂; and
a mass of the nanoparticles in the transparent silica gel layer is 0.5-5% of a mass of the transparent silica gel layer.

9. The anti-ultraviolet blue-free yellow light for the chip process according to claim 7, wherein the OCA glue layer comprises nanoparticles; and the nanoparticles in the OCA glue layer are TiO₂ or ZrO₂; and
a mass of the nanoparticles in the OCA glue layer is 1-40% of a mass of the OCA glue layer.

10. The preparation method of the quantum-dot light conversion film according to claim 2, wherein the nanoparticles are TiO₂ or ZrO₂; and a particle size of the nanoparticles is 50-500 nm;
a mass ratio of the quantum-dot concentrate in the step (1) to the nanoparticles in the step (2) is (1-20):(0.5-5);
in the step (2), the additives comprise polymerization inhibitors and photoinitiators;
a mass of the polymerization inhibitors is 0.01-0.2% of a mass of the light conversion liquid resin in the step (2); and
a mass of the photoinitiators is 0.5-2% of the mass of the light conversion liquid resin in the step (2).

11. The quantum-dot light conversion film according to claim 5, wherein in the step (1) of the preparation method, a wavelength of the quantum-dot concentrate is 580-600 nm;
a mass ratio of the quantum-dot concentrate to the acrylic monomer is (1-20):(5-50);
in the step (1), the high polymer is acrylic and/or thiol; and
in the step (1), a mass ratio of the quantum-dot concentrate to the high polymer is (1-20):(5-50).

12. The quantum-dot light conversion film according to claim 5, wherein in the preparation method, the nanoparticles are TiO₂ or ZrO₂; and a particle size of the nanoparticles is 50-500 nm;
a mass ratio of the quantum-dot concentrate in the step (1) to the nanoparticles in the step (2) is (1-20):(0.5-5);
in the step (2), the additives comprise polymerization inhibitors and photoinitiators;
a mass of the polymerization inhibitors is 0.01-0.2% of a mass of the light conversion liquid resin in the step (2); and
a mass of the photoinitiators is 0.5-2% of the mass of the light conversion liquid resin in the step (2)

13. The quantum-dot light conversion film according to claim 12, wherein in the step (3) of the preparation method, a substrate for coating is alumina or silicon; and a thickness of the substrate is 12-120 μm;
in the step (3), a thickness of the light conversion liquid resin for coating is 50-200 μm; and
in the step (3), an irradiation energy for curing is 500-3000 mJ/cm².

14. The anti-ultraviolet blue-free yellow light for the chip process according to claim 8, wherein the OCA glue layer comprises nanoparticles; and the nanoparticles in the OCA glue layer are TiO₂ or ZrO₂; and
a mass of the nanoparticles in the OCA glue layer is 1-40% of a mass of the OCA glue layer.
